(19) United States
(12) Patent Application Publication
(10) Pub. No.: US 2025/0218833 A1
(43) Pub. Date: Jul. 3, 2025

(54) 3 PILLAR BOAT IN A LOAD LOCK CHAMBER AND METHODS OF MAKING PILLAR BOAT IN LOAD LOCKS FOR SEMICONDUCTOR PROCESSING SYSTEMS

(71) Applicant: ASM IP Holding B.V., Almere (NL)

(72) Inventors: Zentaro Tanaka, Nagaoka-shi (JP); Kyle Tantiwong, Scottsdale, AZ (US); Akira Imai, Tokyo (JP); Samer Banna, Phoenix, AZ (US)

(21) Appl. No.: 19/000,901

(22) Filed: Dec. 24, 2024

Related U.S. Application Data
(60) Provisional application No. 63/615,699, filed on Dec. 28, 2023.

(51) Int. Cl. H01L 21/673

(52) U.S. Cl. CPC H01L 21/67309; H01L 21/67373

(57) ABSTRACT

A wafer boat configured to support one or more wafers is provided. The wafer boat includes a first pillar, second pillar and third pillar, each having a plurality of protrusion elements. Top surfaces of the first, second and third pillar are coupled to a triangular top member and bottom surfaces of the first, second and third pillar are coupled to a triangular bottom member. The wafer boat defines a central axis that extends vertically and is parallel to the first, second and third pillar. The protrusion elements extend towards the central axis to define a plurality of wafer slots, wherein each wafer slot is configured to support a wafer.

### CROSS-REFERENCE TO RELATED APPLICATION(S)

This application claims the benefit of U.S. Provisional Application 63/615,699 filed on Dec. 28, 2023, the entire contents of which are incorporated herein by reference.

### FIELD OF INVENTION

The present disclosure generally relates to fabricating semiconductor devices. More particularly, the present disclosure relates to a wafer boat configured to support a plurality of wafers in load lock chamber.

### BACKGROUND OF THE DISCLOSURE

Semiconductor processing systems, such as semiconductor processing systems with cluster-type platforms, commonly include a front-end connected to a back-end by a load lock. The front-end generally interfaces the semiconductor processing system to the external environment and typically includes a front-end robot to transfer substrates between the front-end of the semiconductor processing system and the load lock. The back-end typically includes a process module wherein substrate processing is accomplished and a back-end robot to transfer substrates between the load lock and the process module. The load lock generally couples the back-end of the semiconductor processing system to the front-end of the semiconductor processing system and is typically arranged to isolate the environment maintained in the back-end of the semiconductor processing system to the environment maintained in the front-end of the semiconductor processing system.

After substrate processing is accomplished in the process module, the substrate is transferred from process module to load lock by the back-end robot before it is transferred to the front-end module. Thus, after substrate processing, the processed wafers are held in load lock chamber for cooling during transition from back-end module to front-end module. In conventional systems, these wafers are held in an apparatus that includes four pillars with semi-circular protrusion elements that extend perpendicularly from the pillars in a horizontal direction. Such a semi-circular protrusion element is generally flat and has a radius of 15 mm. Because these protrusion elements are arranged vertically along the four pillars, the pillars can then be arranged in a manner that defines slots to hold wafers, where each slot is defined by a respective protrusion element extending from each of the four pillars. Accordingly, this conventional arrangement allows the wafers to be stacked one on top of the other.

However, each time the wafer makes contact with an element of the apparatus, particle is generated. The full contact of the wafer with each of the four protrusion elements results in substantial particle residue. In this arrangement, the wafers are stacked in a vertical fashion and any particle residue of a top wafer is deposited on to a wafer below and so on. Further, in conventional systems, the top and bottom members that support the four pillars to form the storage apparatus in the load lock chamber are identical. Accordingly, there is an increased chance of mistakenly switching orientation of the apparatus during installation in the load lock chamber.

Accordingly, there is a need in the art for improved load lock arrangements, semiconductor processing systems having load lock arrangements, material layer deposition methods, and methods of making load lock arrangements for semiconductor processing systems. The present disclosure provides a solution to this need.

### SUMMARY OF THE DISCLOSURE

A wafer boat is provided. The wafer boat is configured to support one or more wafers. The wafer boat comprises a first pillar having a first plurality of protrusion elements, wherein the first pillar is defined by a first inner surface, a first outer surface, a first top surface and a first bottom surface, wherein the first plurality of protrusion elements extend from the first inner surface. The wafer boat further comprises a second pillar having a second plurality of protrusion elements, wherein the second pillar is defined by a second inner surface, a second outer surface, a second top surface and a second bottom surface, wherein the second plurality of protrusion elements extend from the second inner surface. The wafer boat also comprises a third pillar having a third plurality of protrusion elements, wherein the third pillar is defined by a third inner surface, a third outer surface, a third top surface and a third bottom surface, wherein the third plurality of protrusion elements extend from the third inner surface. The wafer boat further comprises a triangular top member having a first top junction, a second top junction and a third top junction, wherein the triangular top plate is coupled to the first pillar, the second pillar and the third pillar, such that the first top surface is coupled to the first top junction, the second top surface is coupled to the second top junction and the third top surface is coupled to the third top junction. The wafer boat also comprises a triangular bottom member having a first bottom junction, a second bottom junction and a third bottom junction, wherein the triangular bottom plate is coupled to the first pillar, the second pillar and the third pillar, such that the first bottom surface is coupled to the first bottom junction, the second bottom surface is coupled to the second bottom junction and the third bottom surface is coupled to the third bottom junction. The triangular top member and the triangular bottom member are parallel to each other. The wafer boat defines a central axis that extends vertically and is further parallel to the first pillar, the second pillar and a third pillar, and wherein the first plurality of protrusion elements, the second plurality of protrusion elements and the third plurality of protrusion elements extend towards the central axis to define a plurality of wafer slots, wherein each wafer slot is configured to support a wafer.

A method of manufacturing a wafer boat is provided. The method includes defining a central axis that extends vertically. The method further includes coupling a first pillar with a triangular top member and a triangular bottom member by coupling a first top surface of the first pillar with a first top junction of the triangular top member and coupling a first bottom surface of the first pillar with a first bottom junction of the triangular bottom member such that a first plurality of protrusion elements extend from a first inner surface toward the central axis. The method also includes coupling a second pillar with the triangular top member and the triangular bottom member by coupling a second top surface of the second pillar with a second top junction of the triangular top member and coupling a second bottom surface of the second pillar with a second bottom junction of the triangular bottom member such that a second plurality of protrusion elements extend from the second inner surface toward the central axis. Finally, the method includes coupling a third pillar with the triangular top member and the triangular bottom member by coupling a third top surface of the third pillar with a third top junction of the triangular top member and coupling a third bottom surface of the third pillar with a third bottom junction of the triangular bottom member such that a third plurality of protrusion elements extend from the third inner surface toward the central axis.

A load lock chamber is provided. The load lock chamber includes a wafer boat having a plurality of pillars. Each of the plurality of pillars comprises a plurality of protrusion elements, wherein each protrusion element comprises a top protrusion surface and a bottom protrusion surface, wherein the bottom protrusion surface is perpendicular to the central axis, and wherein the top protrusion surface is coupled to the bottom protrusion surface at a protrusion angle to form a sloped protrusion element.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a plan view of a wafer boat included in a load lock arrangement of a semiconductor processing system in accordance with the present disclosure;

FIGS. 2A-2C are perspective views of a top and bottom section of a pillar of the wafer boat of FIG. 1;

FIG. 2D is a sectional view of a mid-section of a pillar of the wafer boat of FIG. 1;

FIG. 3A is a perspective view of a top member of the wafer boat of FIG. 1;

FIG. 3B is a top view of a top member of the wafer boat of FIG. 1;

FIG. 4 is a perspective view of a bottom member of the wafer boat of FIG. 1;

FIG. 5A is a sectional view of a wafer placed in a slot of a pillar of the wafer boat of FIG. 1;

FIG. 5B is a perspective view of a wafer placed in a slot of a pillar of the wafer boat of FIG. 1;

FIG. 5C is a top view of a wafer placed in a slot of a pillar of the wafer boat of FIG. 1;

FIG. 6 is a block diagram of a method for manufacturing a wafer boat according to the present disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

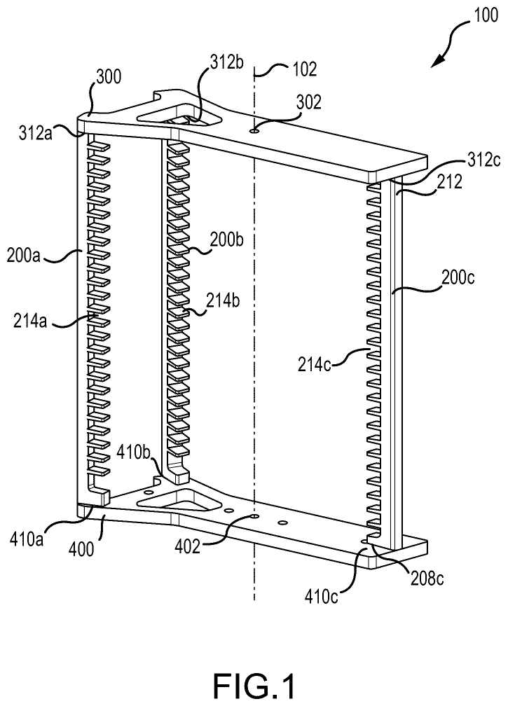

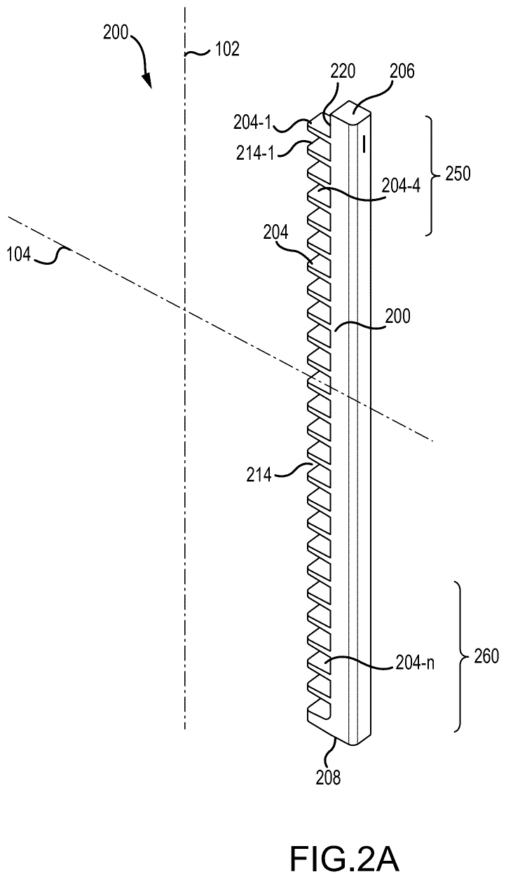

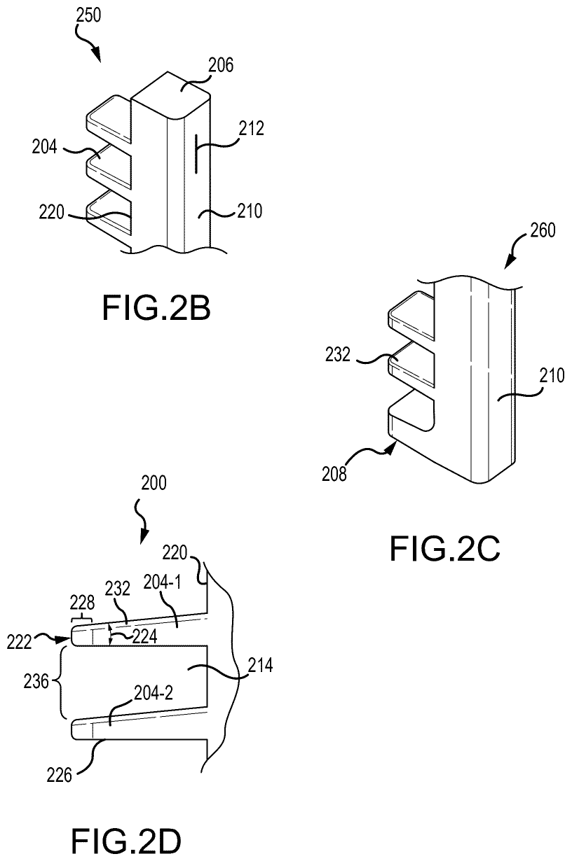

Reference will now be made to the drawings wherein like reference numerals identify similar structural features or aspects of the subject disclosure. For purposes of explanation and illustration, and not limitation, a view of a boat to hold wafers within a load lock arrangement of a semiconductor processing system in accordance with the present disclosure is shown in FIG. 1 and is designated generally by reference character 100. Other examples of boat 100, or aspects thereof, are provided in FIGS. 2-6, as will be described. The systems and methods of the present disclosure may be in semiconductor processing systems employed to fabricate semiconductor devices, such as in semiconductor processing systems employed to deposit material layers using chemical vapor deposition (CVD) and atomic layer deposition (ALD) techniques during the fabrication of logic and memory devices, though the present disclosure is not limited to any semiconductor processing operation or to the fabrication of any particular semiconductor device in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

Referring to FIG. 1, a wafer boat 100 is shown. Wafer boat 100 may be configured to support a plurality of substrates. Wafer boat 100 is placed within a load lock chamber. In exemplary embodiments, the material used to manufacture wafer boat 100 includes quartz material. In exemplary embodiments, other material having the desired quality may be used for manufacturing wafer boat 100. Wafer boat 100 further includes three pillars 200a, 200b, and 200c. In exemplary embodiments, pillars 200a, 200b, and 200c are substantially the same in all respects. Wafer boat 100 further includes a triangular top member 300 and a triangular bottom member 400 that support the pillars 200a, 200b and 200c. In other words, as shown in FIG. 1, triangular top member 300 and triangular bottom member 400 are separated from each other by vertical placement of pillars 200a, 200b and 200c parallel to a vertical axis 102.

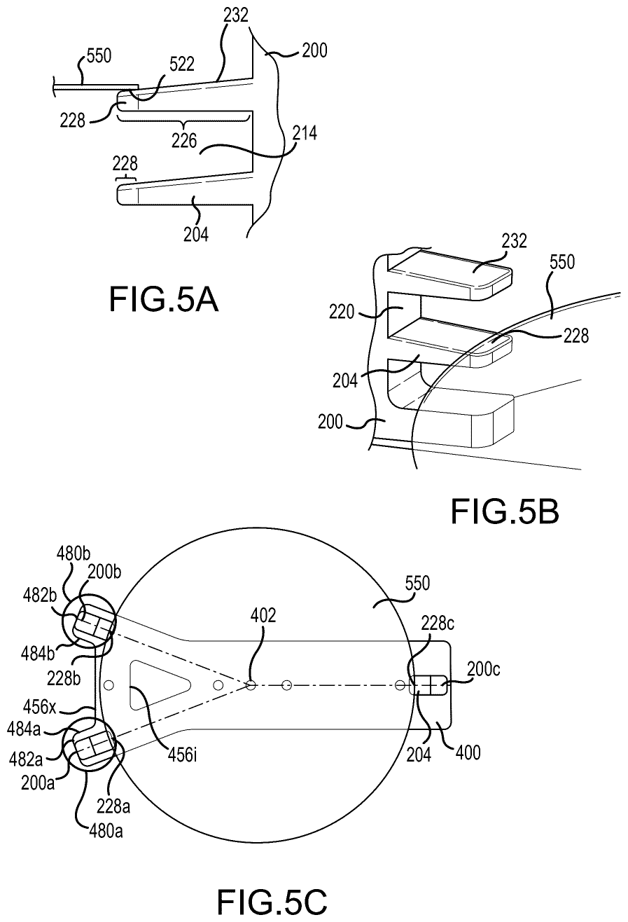

Referring now to FIGS. 2A-2D, pillar 200 is shown. FIG. 2A is a perspective view of pillar 200. Pillar 200 includes any of pillars 200a, 200b or 200c. As shown in FIG. 2A, pillar 200 includes a plurality of protrusion elements 204 that are protruding out of the inner surface 220 of pillar 200. In exemplary embodiments, each pillar 200 includes at least twenty-five protrusion elements (204-1 to 204-25). Each of the protrusion elements 204 are aligned towards its own slot axis 104 (See FIG. 5C). Each slot axis 104 extends through a center point and intersects with vertical axis 102. Protrusion elements 204 of each pillar 200 aligns towards its own slot axis 104, thus forming axes 104, all of which extend through a center point intersecting with vertical axis 102 (See FIG. 5cC). Thus, a protrusion element 204a-1 of the first pillar 200a, a protrusion elements 204b-1 of the second pillar 200b, a protrusion element 204c-1 of the third pillar 200c align along axes 104-1 to form a slot 214-1. Similarly, each of the protrusion elements 204a-n, 204b-n and 204c-n of pillars 200a, 200b and 200c, respectively, align along their respective axes 104-n to form a slot 214-n (See FIG. 1). Each slot 214 is configured to hold a single wafer 550.

Referring now to FIG. 2D, a cross sectional view of pillar 200 is shown. Pillar 200 in FIG. 2D may include any of pillars 200a, 200b or 200c. As shown in FIG. 2D, each protrusion element 204 extends in an angled manner. Each protrusion element 204 includes a top surface 232, a side surface 222 and a bottom surface 226. In exemplary embodiments, bottom surface 226 extends perpendicularly from inner surface 220 of pillar 200 and top surface 232 extends at an obtuse angle from inner surface 220 to form a sloped protrusion element. Top surface 232 and bottom surface 226 are separated by a side surface 222. In exemplary embodiments, side surface 222 measures 3 millimeters (mm). In exemplary embodiments, the angle 224 formed by the top surface 232 and the bottom surface 226 is 5 degrees. In exemplary embodiments, bottom surface 226 measures 220 mm. That is, protrusion element 204 extends out to 220 mm. Further, in exemplary embodiments, distance 236 is defined as the space between the bottom surface of a first protrusion element of pillar 200 (such as 204-1) and a top surface of the next protrusion element of pillar 200 (such as 204-2) and measures at 10 mm.

Referring briefly to FIGS. 2B and 2C, perspective views of a top section 250 of pillar 200 and a bottom section 260 of pillar 200 are shown, respectively. As shown in FIG. 2A, pillar 200 includes a top surface 206, which couples to a top member 300 of boat 100. Top surface 206 is substantially flat to allow easy coupling with top member 300. Pillar 200 also includes an outer surface 210, which is opposite the inner surface 220. Accordingly, pillar 200 includes a substantially rectangular cross section along axis 102. The rectangular section eases the process of manufacturing pillar 200 of boat 100. In exemplary embodiments, outer surface 210 may be further marked with a linear cut mark 212 closer to the top surface 206 to mark orientation. In exemplary embodiments, mark 212 may be a 10 mm long and 0.1 mm deep linear cut on the outer surface 210 parallel to axis 102.

As further seen in FIG. 2C, pillar 200 includes a bottom surface 208, which couples to a bottom member 400 of boat 100. As shown in FIG. 2C, in exemplary embodiments, last protrusion element 204-n is configured to directly couple with bottom member 400. Accordingly, bottom surface 208 of pillar 200 coincides with bottom surface 226 of last protrusion element 204-n. On the contrary, top surface 206 is distinguished from top surface 232 of the first protrusion element 204-1 (See FIG. 2B). Further, unlike top section 250, bottom section 260 does not include a cut mark 212. Thus, mark 212 defines the orientation in which the pillar is to be fitted with top member 300 and bottom member 400 to form boat 100. Such marking prevents directionality fabrication errors during manufacturing of boat 100. As such, during fabrication, the error of top surface 206 coupling with bottom member 400 and consequently, bottom surface 208 coupling with top member 300 is greatly minimized.

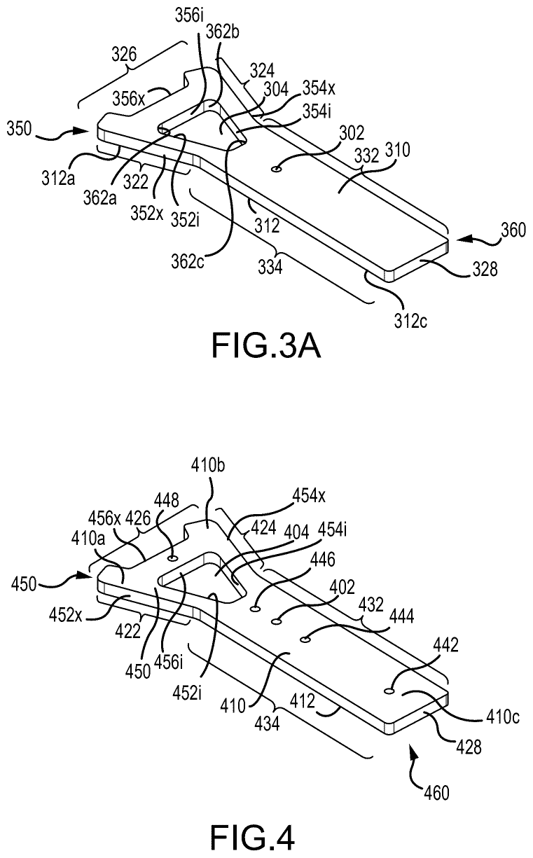

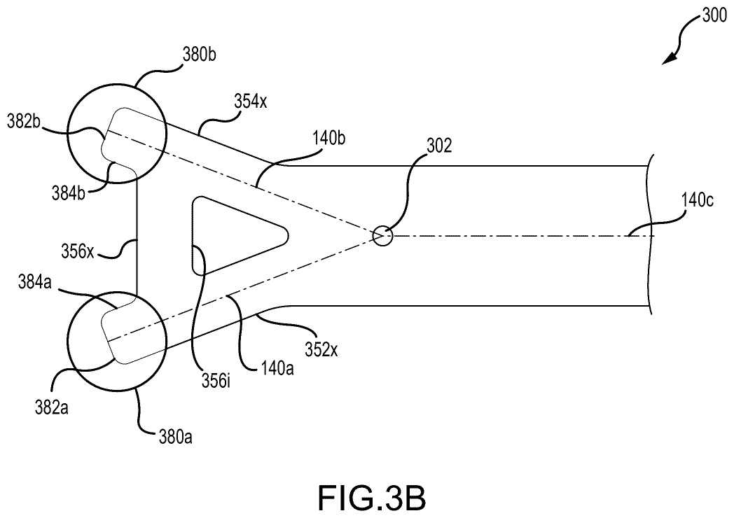

Referring now to FIG. 3A, a triangular top member 300 is shown. Top member 300 includes an upper surface 310 and a lower surface 312. Top member 300 further includes a triangular section 350 and a rectangular section 360. As shown in FIG. 3A, a first side section 322 meets with a second side section 326, which further meets with a third side section 324 to form a triangular section 350 of top member 300. In example embodiments, triangular section 350 further includes a triangular aperture 304 as shown in FIG. 3A. Triangular aperture 304 results in formation of three inner sides 352i, 354i and 356i of triangular section 350. The intersection point of inner sides 352i and 354i may be sharp or rounded. Similarly, the intersection point of inner sides 352i and 356i may be sharp and rounded, and intersection point of inner sides 354i and 356i may be sharp and rounded. Further, sides 352i and 354i form an acute angle 362c, sides 352i and 356i form an acute angle 362a, and sides 354i and 356i form an acute angle 362b. Consequently, triangular aperture 304 forms an acute triangular section. In exemplary embodiments, angle 362a, 362b and 362c are equal to form an equilateral triangular section. In other embodiments, two of angles 362a, 362b and 362c may be equal to form an isosceles triangular section.

As further shown in FIG. 3A, outer side 352x is parallel to inner side 352i, and perpendicular to upper surface 310 and lower surface 312. Outer side 352x meets upper surface 310, upper surface 310 meets inner side 352i, inner side 352i meets lower surface 312, and finally, lower surface 312 meets outer side 352x. Thus, outer side 352x, upper surface 310, lower surface 312 and inner side 352i together form a first side section 322. Similarly, outer side 354x is parallel to inner side 354i, and perpendicular to upper surface 310 and lower surface 312. Outer side 354x meets upper surface 310, upper surface 310 meets inner side 354i, inner side 354i meets lower surface 312, and finally, lower surface 312 meets outer side 354x. Thus, outer side 354x, upper surface 310, lower surface 312 and inner side 354i together form a second side section 324. Finally, outer side 356x is parallel to inner side 356i, and perpendicular to upper surface 310 and lower surface 312. Outer side 356x meets upper surface 310, upper surface 310 meets inner side 356i, inner side 356i meets lower surface 312, and finally, lower surface 312 meets outer side 356x. Thus, outer side 356x, upper surface 310, lower surface 312 and inner side 356i together form at least a part of third side section 326.

In exemplary embodiments, third side section 326 is further divided into three sub-sections. FIG. 3B shows a top view of top triangular member 300. A first sub-section includes outer side 356x, upper surface 310, lower surface 312 and inner side 356i. Further, a second sub-section 380a includes at least a section of outer side 352x that meets with side 382a, and side 382a meets with side 384a (See FIG. 3B). Side 384a is substantially parallel to side 352x. Further, side 382a is perpendicularly aligned with respective axis 104a. Accordingly, at least a section of outer side 352x, side 382a, side 384a, top surface 310 and bottom surface 312 together form a sub-section 380a. As shown in FIG. 3B, sub-section 380a is perpendicularly aligned with axis 104a. Similarly, a third sub-section 380b includes at least a section of outer side 354x that meets with side 382b, and side 382b meets with side 384b (See FIG. 3B). Side 384b is substantially parallel to side 354x. Further, side 382b is perpendicularly aligned with its respective axis 104b. Accordingly, at least a section of outer side 354x, side 382b, side 384b, top surface 310 and bottom surface 312 together form a sub-section 380b. As shown in FIG. 3B, sub-section 380b is perpendicularly aligned with axis 104b. Sub-sections 380a and 380b are separated from each other by 356x. As shown in FIG. 3B, side 384a meets with side 356x such that the intersection point forms an obtuse angle. Similarly, side 384b meets with side 356x such that the intersection point forms an obtuse angle.

Triangular top member 300 further includes a rectangular section 360. Rectangular section 360 includes sides 334, 328 and 332. Rectangular section 360 further includes a upper surface 310 and a lower surface 312. Side 334 and 332 are parallel to each other, and are perpendicular to side 328. Sides 334 and 332 are aligned parallel to axis 104c and side 328 is aligned on an axis perpendicular to axis 104c. As shown in FIG. 3A, sides 328, 332 and 334 meet with upper surface 310 and lower surface 312 to form a rectangular section 360. Accordingly, in exemplary embodiments, rectangular section 360 adjoins with triangular section 350 to form triangular top member 300 to include a single upper surface 310, a single lower surface 312, sides 352x, 354x, 356x, 328, 332, 334, 352i, 354i, 356i, 382a, 382b, 384a, and 384b. Further, in example embodiments, triangular top member 300 includes a single cavity 302 (for example, a hole). Cavity 302 is formed at axis 102. Thus, axis 102 passes through cavity 302. In example embodiments, cavity 302 is formed at the center of triangular top member 300.

Referring now to FIG. 4, a perpendicular view of triangular bottom member 400 is shown. As shown in FIG. 4, triangular bottom member 400 is substantially the same as triangular member 300. However, unlike top member 300, bottom member 400 includes multiple cavities. Like cavity 302, cavity 402 is formed at axis 102. Thus, cavity 402 is aligned with cavity 302 and axis 102 passes through cavity 402. In example embodiments, bottom member 400 includes two cavities 446 and 444 on either side of cavity 402 and are substantially the same size as cavity 402. Further, bottom member 400 may include cavity 442 such that cavity 442 aligns with pillar 200c after formation of boat 100 (See FIG. 1). Bottom member 400 may also include a cavity 448 opposite to cavity 442. Cavities 402, 442, 444, 446 and 448 are all positioned along axis 104c (See FIG. 5C). Cavities 444 and 446 that are positioned on either side of cavity 402 may be utilized by a lower mounting plate attached to load lock chamber. Since cavities 444 and 446 are not included in top member 300, top member 300 is distinguished from bottom member 400 and upside-down installation of boat 100 is prevented.

Bottom member 400 is substantially the same as top member 400 in all other respects. Similar to top member 300, bottom member 400 includes a triangular section 450 and a rectangular section 460. As shown in FIG. 4, a first side section 422 meets with a second side section 426, which further meets with a third side section 424 to form a triangular section 450 of bottom member 400. In example embodiments, triangular section 450 further includes a triangular aperture 404 as shown in FIG. 4. Triangular aperture 404 is similar in size and shape to triangular aperture 304.

Triangular aperture 404 results in formation of three inner sides 452i, 454i and 456i of triangular section 450. The intersection point of inner sides 452i and 454i may be sharp or rounded. Similarly, the intersection point of inner sides 452i and 456i may be sharp and rounded, and intersection point of inner sides 454i and 456i may be sharp and rounded. Further, sides 452i and 454i form an acute angle 462c, sides 452i and 456i form an acute angle 462a, and sides 454i and 456i form an acute angle 462b. Consequently, triangular aperture 404 forms an acute triangular section. In exemplary embodiments, angle 462a, 462b and 462c are equal to form an equilateral triangular section. In other embodiments, two of angles 462a, 462b and 462c may be equal to form an isosceles triangular section.

As further shown in FIG. 4, outer side 452x is parallel to inner side 452i, and perpendicular to upper surface 410 and lower surface 412. Outer side 452x meets upper surface 410, upper surface 410 meets inner side 452i, inner side 452i meets lower surface 412, and finally, lower surface 412 meets outer side 452x. Thus, outer side 452x, upper surface 410, lower surface 412 and inner side 452i together form a first side section 422. Similarly, outer side 454x is parallel to inner side 454i, and perpendicular to upper surface 410 and lower surface 412. Outer side 454x meets upper surface 410, upper surface 410 meets inner side 454i, inner side 454i meets lower surface 412, and finally, lower surface 412 meets outer side 454x. Thus, outer side 454x, upper surface 410, lower surface 412 and inner side 454i together form a second side section 424. Finally, outer side 456x is parallel to inner side 456i, and perpendicular to upper surface 410 and lower surface 412. Outer side 456x meets upper surface 410, upper surface 410 meets inner side 456i, inner side 456i meets lower surface 412, and finally, lower surface 412 meets outer side 456x. Thus, outer side 456x, upper surface 410, lower surface 412 and inner side 456i together form at least a part of third side section 426.

In exemplary embodiments, third side section 426 is divided into three sub-sections. A first sub-section includes outer side 456x, upper surface 410, lower surface 412 and inner side 456i (See the top view of bottom member 400 shown in FIG. 5C). Further, a second sub-section 480a includes at least a section of outer side 452x that meets with side 482a, and side 482a meets with side 484a (See FIG. 5C). Side 484a is substantially parallel to side 452x. Further, side 482a is perpendicularly aligned with respective axis 104a. Accordingly, at least a section of outer side 452x, side 482a, side 484a, top surface 410 and bottom surface 412 together form a sub-section 480a, which is perpendicularly aligned with axis 104a (See FIG. 5C). Similarly, a third sub-section 480b includes at least a section of outer side 454x that meets with side 482b, and side 482b meets with side 484b (See FIG. 5C). Side 484b is substantially parallel to side 454x. Further, side 482b is perpendicularly aligned with its respective axis 104b. Accordingly, at least a section of outer side 454x, side 482b, side 484b, top surface 410 and bottom surface 412 together form a sub-section 480b, and sub-section 480b is perpendicularly aligned with axis 104b (See FIG. 5C). Sub-sections 480a and 480b are separated from each other by 456x. Side 484a meets with side 456x such that the intersection point forms an obtuse angle. Similarly, side 484b meets with side 456x such that the intersection point forms an obtuse angle (See FIG. 5C).

Triangular bottom member 400 further includes a rectangular section 460. Rectangular section 460 includes sides 434, 428 and 432. Rectangular section 460 further includes an upper surface 410 and a lower surface 412. Side 434 and 432 are parallel to each other, and are perpendicular to side 428. Sides 434 and 432 are aligned parallel to axis 104c and side 428 is aligned on an axis perpendicular to axis 104c. As shown in FIG. 4, sides 428, 432 and 434 meet with upper surface 410 and lower surface 412 to form a rectangular section 460. Accordingly, in exemplary embodiments, rectangular section 460 adjoins with triangular section 450 to form triangular bottom member 400 to include a single upper surface 410, a single lower surface 412, sides 452x, 454x, 456x, 428, 432, 434, 452i, 454i, 456i, 482a, 482b, 484a, and 484b.

Referring back to FIG. 1, top member 300 and bottom member 400 are separated by pillar(s) 200a, 200b and 200c to form boat 100. As shown in FIG. 1, top member 300 and bottom member 400 are arranged such that aperture 304 is vertically aligned with aperture 404 along an axis parallel to axis 102. As further shown in FIG. 1, cavity 302 and cavity 402 are also aligned along axis 102. Top surface 206 of pillar 200a is attached to lower surface 312 of member 300 at junction spot 312a. Similarly, top surface 206 of pillar 200b is attached to lower surface 312 of member 300 at junction spot 312b, and top surface 206 of pillar 200c is attached to lower surface 312 at junction spot 312c. Bottom surface 208 of pillar 200a is attached to top surface 410 of member 400 at junction spot 410a, bottom surface 208 of pillar 200b is attached to bottom surface 410 of member 400 at junction spot 410b, and bottom surface 208 of pillar 200c is attached to bottom surface 410 of member 400 at junction spot 410c.

As shown in FIG. 1, such an arrangement results in triangular formation for each of the slots 214 to support wafer 550. Accordingly, a first wafer 550-1 can be supported by slots 214a-1, 214b-1 and 214c-2, a second wafer 550-2 can be supported by slots 214a-2, 214b-2 and 214c-2, and so on. In the example embodiment provided herein, twenty-five wafers can be supported by boat 100.

FIGS. 5A-5C show an example wafer 550 supported by one or more protrusion element(s) 204. FIG. 5A shows a side view of a section of pillar 200. As shown in FIG. 5B, wafer 550 rests on a small segment 228 of top protrusion surface 232. In exemplary embodiments, segment 228 is 3.5 mm long. Accordingly, contact 552 between wafer 550 and protrusion element 204 is minimal. Further, because surface 232 is formed at an angle, wafer 550 does not exactly rest flat on top surface 232. Thus, contact 552 is further reduced. Accordingly, particle residue that may result due to contact between wafer 550 and boat 100 is greatly reduced.

FIG. 5C shows a top view of wafer 550 supported by boat 100. Wafer 550 is supported by protrusion element 204a of pillar 200a, protrusion element 204b of pillar 200b and protrusion element 204c of pillar 200c. As shown in FIG. 5C, protrusion elements 204a, 204b and 204c extend inwards along slot axes 104 (each axis 104 includes a respective axis 104a, 104b and 104c that intersect at central axis 102). Wafer 550 rests on segments 228a, 228b and 228c of protrusion elements 204a, 204b and 204c. The hybrid between a triangular section (including pillars 200a and 200b) adjoined with a rectangular section (including pillar 200c), as shown in FIG. 5C, provides a stable support for wafer 550 while keeping the contact of wafer 550 with the pillars in each slot 214 minimal.

Advantageously, relative to a wafer storage rack having four pillars (e.g., a four-pillar arrangement), the inventors expected a twenty-five percent improvement in contamination performance as reflected by particular count attributable to the relatively small number of wafer contact points relative to a wafer rack having four pillars. Unexpectedly, experimental testing of the above-described wafer storage rack with three pillars exhibited a contamination on the order of approximately eighty percent relative to a wafer storage rack having four pillars. In this respect experimental testing showed that defects, e.g., defects associated with particles resulting from contact between wafer 550 and boat 100 in the above-described three pillar configuration disclosed herein were less than twenty percent of the particle generation in a wafer storage rack constructed to have four pillars.

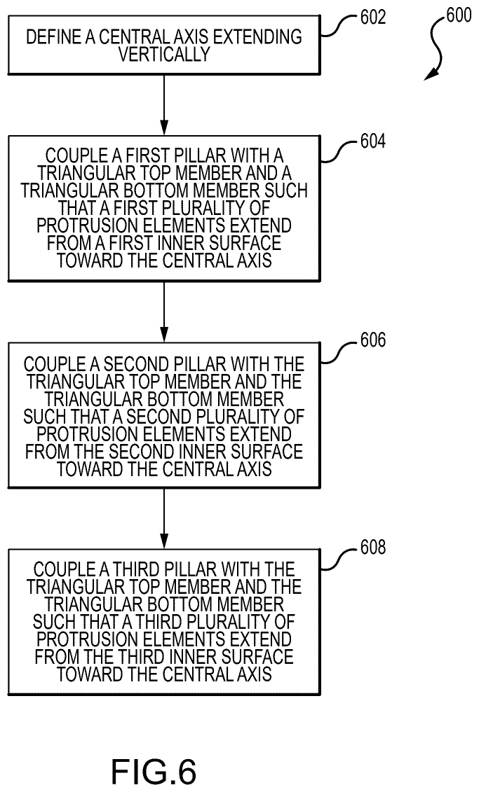

With reference to FIG. 6, a method of manufacturing a boat, e.g., boat 100 (shown in FIG. 1), is shown. Method 600 includes defining a central axis (such as axis 102) that extends vertically, as shown with box 602. Method 600 further includes coupling a first pillar (such as, pillar 200a) with a triangular top member (such as, member 300) and a triangular bottom member (such as, member 400) such that a first plurality of protrusion elements extends from a first inner surface (such as surface 220) toward the central axis, as shown with box 604. In exemplary embodiments, the first pillar is coupled with a triangular top member and a triangular bottom member by coupling a first top surface (such as surface 206) of the first pillar with a first top junction (such as junction spot 312a) of the triangular top member and coupling a first bottom surface of the first pillar with a first bottom junction (such as surface 412a) of the triangular bottom member.

Method 600 further includes coupling a second pillar (such as, pillar 200b) with a triangular top member (such as, member 300) and a triangular bottom member (such as, member 400) such that a second plurality of protrusion elements extend from a second inner surface (such as surface 220) toward the central axis, as shown with box 606. In exemplary embodiments, the second pillar is coupled with a triangular top member and a triangular bottom member by coupling a second top surface (such as surface 206) of the second pillar with a second top junction (such as junction spot 312b) of the triangular top member and coupling a second bottom surface of the second pillar with a second bottom junction (such as surface 412b) of the triangular bottom member.

Method 600 further includes coupling a third pillar (such as, pillar 200c) with a triangular top member (such as, member 300) and a triangular bottom member (such as, member 400) such that a third plurality of protrusion elements extend from a third inner surface (such as surface 220) toward the central axis. In exemplary embodiments, the third pillar is coupled with a triangular top member and a triangular bottom member by coupling a third top surface (such as surface 206) of the third pillar with a third top junction (such as junction spot 312c) of the triangular top member and coupling a third bottom surface of the third pillar with a third bottom junction (such as surface 412c) of the triangular bottom member.

In exemplary embodiments, each protrusion element (such as protrusion element 204) includes a top protrusion surface (such as top surface 232) and a bottom protrusion surface (such as bottom surface 226), wherein the bottom protrusion surface is perpendicular to the central axis, and wherein the top protrusion surface is coupled to the bottom protrusion surface at a protrusion angle to form a sloped protrusion element. In exemplary embodiments, method 600 includes identifying the first top surface by identifying a first linear cut mark on a first outer surface of the first pillar, identifying the second top surface of the second pillar by identifying a second linear cut mark on a second outer surface of the second pillar, and identifying the third top surface of the third pillar by identifying a third linear cut mark on a third outer surface of the third pillar.

In exemplary embodiments, method 600 further includes identifying the triangular top member as a member having a single cavity hole and identifying the triangular bottom member as a member having a plurality of cavity holes. In exemplary embodiments of method 600, triangular top member further includes a top triangle section (such as the triangle section 350) that adjoins with a top rectangle section (such as the rectangle section 360) to form the triangular top member such that the top triangle section further includes a top triangular aperture. In exemplary embodiments of method 600, the triangular bottom member includes a bottom triangle section (such as the triangle section 450) that adjoins with a bottom rectangle section (such as the rectangle section 460) to form the triangular bottom member such that the bottom triangle section further includes a bottom triangular aperture. In exemplary embodiments, method 600 further includes aligning the top triangular aperture and the bottom triangular aperture in parallel with each other such that an aperture axis parallel to the central axis perpendicularly passes through the top triangular aperture and the bottom triangular aperture.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

What is claimed is:

1. A wafer boat configured to support one or more wafers, the wafer boat comprising:
a first pillar having a first plurality of protrusion elements, wherein the first pillar is defined by a first inner surface, a first outer surface, a first top surface and a first bottom surface, wherein the first plurality of protrusion elements extend from the first inner surface;
a second pillar having a second plurality of protrusion elements, wherein the second pillar is defined by a second inner surface, a second outer surface, a second top surface and a second bottom surface, wherein the second plurality of protrusion elements extend from the second inner surface;
a third pillar having a third plurality of protrusion elements, wherein the third pillar is defined by a third inner surface, a third outer surface, a third top surface and a third bottom surface, wherein the third plurality of protrusion elements extend from the third inner surface;
a triangular top member having a first top junction, a second top junction and a third top junction, wherein the triangular top member is coupled to the first pillar, the second pillar and the third pillar, such that the first top surface is coupled to the first top junction, the second top surface is coupled to the second top junction and the third top surface is coupled to the third top junction; and
a triangular bottom member having a first bottom junction, a second bottom junction and a third bottom junction, wherein the triangular bottom member is coupled to the first pillar, the second pillar and the third pillar, such that the first bottom surface is coupled to the first bottom junction, the second bottom surface is coupled to the second bottom junction and the third bottom surface is coupled to the third bottom junction,
wherein the triangular top member and the triangular bottom member are parallel to each other, wherein the wafer boat defines a central axis that extends vertically and is further parallel to the first pillar, the second pillar and the third pillar, and wherein the first plurality of protrusion elements, the second plurality of protrusion elements and the third plurality of protrusion elements extend towards the central axis to define a plurality of wafer slots, wherein each wafer slot is configured to support a wafer.

2. The wafer boat of claim 1, wherein each protrusion element comprises a top protrusion surface and a bottom protrusion surface, wherein the bottom protrusion surface is perpendicular to the central axis, and wherein the top protrusion surface is coupled to the bottom protrusion surface at a protrusion angle to form a sloped protrusion element.

3. The wafer boat of claim 2, wherein the protrusion angle is five degrees.

4. The wafer boat of claim 2, wherein each protrusion element further comprises a side protrusion surface such that bottom protrusion surface is coupled to the side protrusion surface, and wherein the side protrusion surface is coupled to the top protrusion surface and is 3 millimeters.

5. The wafer boat of claim 2, wherein the bottom protrusion surface is 20 millimeters.

6. The wafer boat of claim 2, wherein the top protrusion surface of each protrusion element comprises a wafer segment such that the wafer supported by the protrusion element is only limited to contact within the wafer segment.

7. The wafer boat of claim 6, wherein the wafer segment is 3.5 millimeters.

8. The wafer boat of claim 1, wherein the first outer surface comprises a first linear cut mark such that the first linear cut mark is closer to the first top surface than the first bottom surface, wherein the second outer surface comprises a second linear cut mark such that the second linear cut mark is closer to the second top surface in comparison to the second bottom surface, and wherein the third outer surface comprises a third linear cut mark such that the third linear cut mark is closer to the third top surface in comparison the third bottom surface.

9. The wafer boat of claim 1,
wherein the triangular top member is defined by a top triangle section and a top rectangle section such that the top triangle section comprises the first top junction and the second top junction and the top rectangle section comprises the third top junction; and
wherein the triangular bottom member is defined by a bottom triangle section and a bottom rectangle section such that the bottom triangle section comprises the first bottom junction and the second bottom junction and the bottom rectangle section comprises the third bottom junction.

10. The wafer boat of claim 9, wherein the triangular top member comprises a triangular top aperture, wherein the triangular bottom member comprises a triangular bottom aperture, and wherein the triangular top aperture and the triangular bottom aperture are vertically aligned along an axis parallel to the central axis.

11. The wafer boat of claim 9, wherein the triangular top member comprises a top central cavity hole, and wherein the triangular bottom member comprises a bottom central cavity hole, and wherein the top central cavity hole and the bottom central cavity hole are aligned along the central axis.

12. The wafer boat of claim 11, wherein the triangular bottom member comprises a plurality of cavity holes.

13. The wafer boat of claim 12, wherein the plurality of cavity holes comprises a first cavity hole formed at the third bottom junction, a second cavity hole formed between the bottom central cavity hole and the second cavity hole, a third cavity hole formed between a triangular bottom aperture and the bottom central cavity hole, and a fourth cavity hole formed between the first bottom junction and the second bottom junction, wherein the first cavity hole, the second cavity hole, the third cavity hole, the fourth cavity hole and the bottom central cavity hole align along a slot axis respective to the third pillar.

14. A method of manufacturing a wafer boat, comprising:
defining a central axis that extends vertically;
coupling a first pillar with a triangular top member and a triangular bottom member by coupling a first top surface of the first pillar with a first top junction of the triangular top member and coupling a first bottom surface of the first pillar with a first bottom junction of the triangular bottom member such that a first plurality of protrusion elements extend from a first inner surface toward the central axis;
coupling a second pillar with the triangular top member and the triangular bottom member by coupling a second top surface of the second pillar with a second top junction of the triangular top member and coupling a second bottom surface of the second pillar with a second bottom junction of the triangular bottom member such that a second plurality of protrusion elements extend from a second inner surface toward the central axis; and
coupling a third pillar with the triangular top member and the triangular bottom member by coupling a third top surface of the third pillar with a third top junction of the triangular top member and coupling a third bottom surface of the third pillar with a third bottom junction of the triangular bottom member such that a third plurality of protrusion elements extend from a third inner surface toward the central axis.

15. The method of claim 14,
wherein each protrusion element comprises a top protrusion surface and a bottom protrusion surface, wherein the bottom protrusion surface is perpendicular to the central axis, and
wherein the top protrusion surface is coupled to the bottom protrusion surface at a protrusion angle to form a sloped protrusion element.

16. The method of claim 14,
wherein coupling the first top surface of the first pillar with the first top junction of the triangular top member further comprises identifying the first top surface of the first pillar by identifying a first linear cut mark on a first outer surface of the first pillar;
wherein coupling the second top surface of the second pillar with the second top junction of the triangular top member further comprises identifying the second top surface of the second pillar by identifying a second linear cut mark on a second outer surface of the second pillar; and
wherein coupling the third top surface of the third pillar with the third top junction of the triangular top member further comprises identifying the third top surface of the third pillar by identifying a third linear cut mark on a third outer surface of the third pillar.

17. The method of claim 14,
wherein coupling the first pillar with the triangular top member and the triangular bottom member, coupling the second pillar with the triangular top member and the triangular bottom member and coupling the third pillar with the triangular top member and the triangular bottom member further comprises identifying the triangular top member as a member having a single cavity hole and identifying the triangular bottom member as the member having a plurality of cavity holes.

18. The method of claim 14,
wherein the triangular top member comprises a top triangle section that adjoins with a top rectangle section to form the triangular top member such that the top triangle section further comprises a top triangular aperture,
wherein the triangular bottom member comprises a bottom triangle section that adjoins with a bottom rectangle section to form the triangular bottom member such that the bottom triangle section further comprises a bottom triangular aperture, and
wherein coupling the first pillar with the triangular top member and the triangular bottom member, coupling the second pillar with the triangular top member and the triangular bottom member and coupling the third pillar with the triangular top member and the triangular bottom member further comprises aligning the top triangular aperture and the bottom triangular aperture in parallel with each other such that an aperture axis parallel to the central axis perpendicularly passes through the top triangular aperture and the bottom triangular aperture.

19. A load lock chamber comprises:
a wafer boat having a plurality of pillars, wherein each of the plurality of pillars comprises a plurality of protrusion elements, wherein each protrusion element comprises a top protrusion surface and a bottom protrusion surface, wherein the bottom protrusion surface is perpendicular to a central axis, and wherein the top protrusion surface is coupled to the bottom protrusion surface at a protrusion angle to form a sloped protrusion element.

20. The load lock chamber of claim 19, further comprising:
a triangular top member coupled to each of the plurality of pillars; and
a triangular bottom member coupled to each of the plurality of pillars such that the triangular top member and the triangular bottom member are coupled parallel to each other.
